(19) United States
(12) Patent Application Publication
(10) Pub. No.: US 2024/0324255 A1
(43) Pub. Date: Sep. 26, 2024

(54) SOLAR CELL

(71) Applicant: Panasonic Holdings Corporation, Osaka (JP)

(72) Inventor: Takeyuki SEKIMOTO, Osaka (JP)

(73) Assignee: Panasonic Holdings Corporation, Osaka (JP)

(21) Appl. No.: 18/733,405

(22) Filed: Jun. 4, 2024

Related U.S. Application Data
(63) Continuation of application No. PCT/JP2022/042297, filed on Nov. 14, 2022.

(30) Foreign Application Priority Data
Dec. 7, 2021 (JP) 2021-198905

(51) Int. Cl. H10K 30/80; H10K 30/40; H10K 85/50; H10K 85/60

(52) U.S. Cl. CPC H10K 30/80; H10K 30/40; H10K 85/50; H10K 85/654; H10K 85/6572

(57) ABSTRACT

A solar cell 100 of the present disclosure includes a first electrode 20, an electron transport layer 30, an intermediate layer 70, a photoelectric conversion layer 40, and a second electrode 60. The first electrode 20, the electron transport layer 30, the intermediate layer 70, and the photoelectric conversion layer 40 are disposed in this order. The photoelectric conversion layer 40 includes a perovskite compound. The intermediate layer 70 includes a heterocyclic compound. The heterocyclic compound includes a six-membered ring including an element having a lone pair. In the solar cell 100, the photoelectric conversion layer 40 and the intermediate layer 70 may be disposed in contact with each other.

This application is a continuation of PCT/JP2022/042297 filed on Nov. 14, 2022, which claims foreign priority of Japanese Patent Application No. 2021-198905 filed on Dec. 7, 2021, the entire contents of both of which are incorporated herein by reference.

### BACKGROUND OF THE INVENTION

### 1. Field of the Invention

The present invention relates to a solar cell.

### 2. Description of Related Art

Research and development of perovskite solar cells in which a perovskite crystal represented by a composition formula ABX₃ (where A is a monovalent cation, B is a divalent cation, and X is a halogen anion) or a structure similar thereto (hereinafter referred to as “perovskite compound”) is used as a photoelectric conversion material have been conducted recently. Various approaches have been made to enhance the photoelectric conversion efficiency, the durability, or the light resistance of perovskite solar cells.

Non Patent Literature 1 (T. Sekimoto, and five others, ACS Applied Energy Materials, June 2019, vol. 2, pp. 5039-5049) reports the result of analyzing changes in chemical bond states before and after light irradiation of an interface between an electron transport layer and a photoelectric conversion layer of a perovskite solar cell and an interface between the photoelectric conversion layer and a hole transport layer of the perovskite solar cell by hard X-ray photoelectron spectroscopy. In the case where the perovskite solar cell is left open under light irradiation, while iodine with a valence of 0 (I⁰ or I²) in a perovskite compound being a photoelectric conversion material is accumulated near the interface between the photoelectric conversion layer and the hole transport layer, Pb⁰ is accumulated at the interface between the electron transport layer and the photoelectric conversion layer. A model is proposed in which iodine vacancies are accumulated near the interface between the electron transport layer and the photoelectric conversion layer as a consequence of accumulation of iodine near the interface between the photoelectric conversion layer and the hole transport layer. Non Patent Literature 1 suggests that suppress of a cathode reaction (Pb²⁺+2e⁻→Pb⁰) at the interface between the electron transport layer and the photoelectric conversion layer is effective for suppressing photodegradation of the perovskite solar cell.

Non Patent Literature 2 (Azat F. Akbulatov, and 10 others, The Journal of Physical Chemistry Letters, December 2019, vol. 11, pp. 333-339) reports that a perovskite compound is partly decomposed in a reversible manner by heat or light irradiation even in the absence of oxygen and humidity. For example, CH₃NH₃PbI₃ is decomposed into PbI₂ and CH₃NH₃I. Furthermore, the process of decomposition of PbI₂ into Pb⁰ and I₂ and the process of decomposition of CH₃NH₃I into CH₃I, NH₃, and other compounds are shown.

Non Patent Literature 3 (Michael L. Agiorgousis, and three others, Journal of the American Chemical Society, September 2014, vol. 136, pp. 14570-14575) reveals by density functional theory (DFT) calculation that, as for CH₃NH₃PbI₃ being a perovskite compound included in perovskite solar cells, an iodine ion entering the A site forms an iodine trimer forming a deep defect level in a band gap.

### SUMMARY OF THE INVENTION

The present disclosure aims to provide a solar cell having a configuration suitable for enhancing the thermal resistance.

The solar cell of the present disclosure includes a first electrode, an electron transport layer, an intermediate layer, a photoelectric conversion layer, and a second electrode, wherein
the first electrode, the electron transport layer, the intermediate layer, and the photoelectric conversion layer are disposed in this order,
the photoelectric conversion layer includes a perovskite compound,
the intermediate layer includes a heterocyclic compound, and
the heterocyclic compound includes a six-membered ring including an element having a lone pair.

The present disclosure provides a solar cell having a configuration suitable for enhancing the thermal resistance.

### BRIEF DESCRIPTION OF THE DRAWINGS

FIG. 1 schematically shows behaviors of an X ion and an electron in an electron transport layer and a photoelectric conversion layer.

FIG. 2 schematically shows behaviors of an X ion and an electron in an electron transport layer, an intermediate layer, and a photoelectric conversion layer.

FIG. 3 schematically shows a cross-sectional view of a solar cell 100 of a first embodiment.

FIG. 4 schematically shows a cross-sectional view of a solar cell 200 of a second embodiment.

### DETAILED DESCRIPTION

<Findings on which the Present Disclosure is Based>

The types of defects in a perovskite compound are, for example, an atomic vacancy, an interstitial atom, and substitution of atoms at each site (namely, A, B, and X) of ABX₃. The types and locations of defects formed in a perovskite compound can vary depending not only on the composition of the perovskite compound and the method for producing the perovskite compound but also on heat stress, light irradiation, and an ambient environment such as oxygen and humidity, as described in Non Patent Literatures 1 to 3. For example, when a perovskite solar cell is left open in a dark state, the direction of a built-in electric field in the perovskite is opposite to that under light irradiation; therefore, anions at the X sites (hereinafter referred to as “X ions”) tend to be concentrated at the interface between the electron transport layer and the photoelectric conversion layer, and A-site cations tend to be concentrated at the interface between the photoelectric conversion layer and the hole transport layer. Heating accelerates ion migration, promoting the concentration of these ions. For example, in the case of CH₃NH₃PbI₃, an iodine ion corresponding to the X ion enters the A site to cause rearrangement of iodine, and thereby an I trimer forming a deep defect level in a band gap is formed (refer to Non Patent Literature 3). In a dark state, since A-site cations (hereinafter referred to as “A ions”) are concentrated at the interface between the photoelectric conversion layer and the hole transport layer, vacancies are formed at A sites at the interface between the electron transport layer and the photoelectric conversion layer. At the same time, X ions concentrated near the interface between the electron transport layer and the photoelectric conversion layer enter the A-site vacancies and eventually form X trimers.

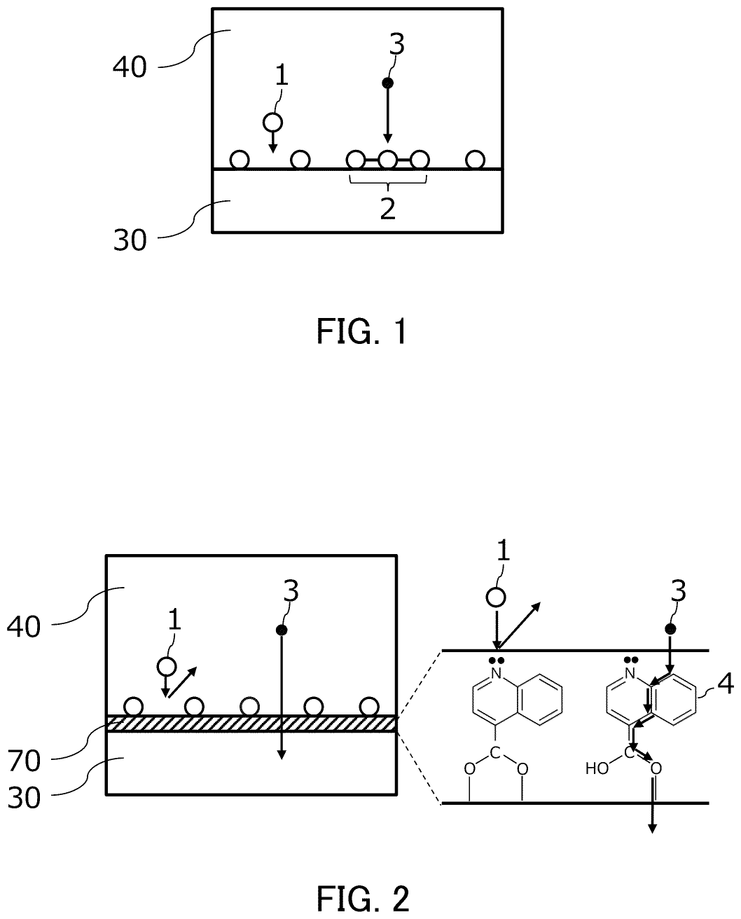

FIG. 1 schematically shows behaviors of an X ion and an electron in an electron transport layer and a photoelectric conversion layer. FIG. 1 shows behaviors of an X ion 1 and an electron 3 in an electron transport layer 30 and a photoelectric conversion layer 40 in a dark state.

As shown in FIG. 1, the X ion 1 enters an A-site vacancy near the interface between the photoelectric conversion layer 40 and the electron transport layer 30 to form an X trimer 2. The X trimer 2 has a deep defect level and captures the electron 3.

The X trimer 2 forms a deep defect level in a band gap of the perovskite near the interface between the electron transport layer 30 and the photoelectric conversion layer 40. This X trimer 2 captures the electron 3, and therefore current leakage increases and the photoelectric conversion efficiency (particularly, the output under a low illuminance condition) decreases. Moreover, in this case, heating accelerates ion migration to further promote concentration of ions, and therefore the decrease in output is further promoted. As just described, perovskite solar cells held in a dark state conventionally have room for improvement in thermal durability.

Therefore, in order to improve the thermal durability of a perovskite solar cell, it is necessary to prevent X ions from being concentrated near the interface between the electron transport layer and the photoelectric conversion layer and forming X trimers.

Thus, the present inventor made intensive studies for a configuration capable of reducing formation of an X trimer near the interface between the electron transport layer and the photoelectric conversion layer. Consequently, the present inventor newly found an intermediate layer capable of reducing concentration of X ions near the interface between the electron transport layer and the photoelectric conversion layer, and has completed a new solar cell in which the intermediate layer is provided between the electron transport layer and the photoelectric conversion layer. The intermediate layer newly found as a result of the intensive studies by the present inventor includes a heterocyclic compound, and the heterocyclic compound includes at least one six-membered ring including an element having a lone pair.

FIG. 2 schematically shows behaviors of an X ion and an electron in an electron transport layer, an intermediate layer, and a photoelectric conversion layer. As shown in FIG. 2, an intermediate layer 70 is disposed between the electron transport layer 30 and the photoelectric conversion layer 40. The intermediate layer 70 includes a heterocyclic compound 4. The heterocyclic compound 4 includes at least one six-membered ring including an element having a lone pair. Since the lone pair included in the heterocyclic compound repels the X ion 1, the X ion 1 cannot enter an A-site vacancy. Therefore, concentration of the X ions 1 at the interface between the electron transport layer 30 and the photoelectric conversion layer 40 is reduced. Consequently, the photoelectric conversion efficiency and the thermal resistance are improved. FIG. 2 shows 4-quinolinecarboxylic acid as an example of the heterocyclic compound 4. For example, a lone pair of the nitrogen atom included in a quinoline ring faces the photoelectric conversion layer 40, and the oxygen atom in the carboxyl group is self-organized as an anchor toward the electron transport layer 30.

The introduction of the intermediate layer 70 also suppresses photodegradation by a cathode reaction at the interface between the electron transport layer and the photoelectric conversion layer, the cathode reaction being mentioned in Non Patent Literature 1. That is, the provision of the intermediate layer 70 improves the light resistance as well was the thermal resistance as described above.

### EMBODIMENTS OF PRESENT DISCLOSURE

### First Embodiment

A solar cell of a first embodiment includes a first electrode, an electron transport layer, an intermediate layer, a photoelectric conversion layer, and a second electrode. The first electrode, the electron transport layer, the intermediate layer, and the photoelectric conversion layer are disposed in this order. The photoelectric conversion layer includes a perovskite compound. The intermediate layer includes a heterocyclic compound. The heterocyclic compound includes a six-membered ring including an element having a lone pair. The solar cell of the first embodiment may include the first electrode, the electron transport layer, the intermediate layer, the photoelectric conversion layer, and the second electrode in this order.

The solar cell of the first embodiment may further include a hole transport layer disposed between the photoelectric conversion layer and the second electrode.

Since having the above intermediate layer, the solar cell of the first embodiment can reduce concentration of X ions at a surface of the photoelectric conversion layer on the electron transport layer side in a dark state. Consequently, formation of an X trimer can be reduced. Hence, the solar cell of the first embodiment can enhance the thermal resistance. That is, the solar cell of the first embodiment has a configuration suitable for enhancing the thermal resistance. Of the interfaces between the photoelectric conversion layer and its adjacent layers, the surface of the photoelectric conversion layer on the electron transport layer side refers to the interface closer to the electron transport layer.

Furthermore, the introduction of the above intermediate layer allows the solar cell of the first embodiment to suppress a light-irradiation-induced cathode reaction at the surface of the photoelectric conversion layer on the electron transport layer side. Hence, the solar cell of the first embodiment can also enhance the light resistance.

The solar cell of the present disclosure will be hereinafter described in details with reference to the drawings.

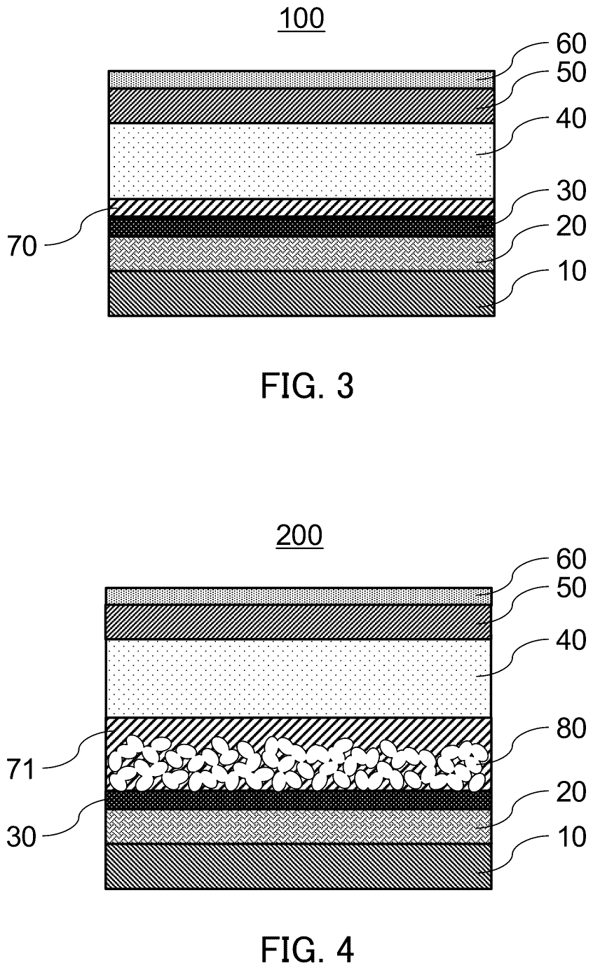

FIG. 3 schematically shows a cross-sectional view of a solar cell 100 of the first embodiment.

The solar cell 100 includes a substrate 10, a first electrode 20, an electron transport layer 30, a photoelectric conversion layer 40, an intermediate layer 70, a hole transport layer 50, and a second electrode 60 in this order.

The photoelectric conversion layer 40 includes a perovskite compound.

The intermediate layer 70 includes a heterocyclic compound. The heterocyclic compound includes a six-membered ring including an element having a lone pair. This heterocyclic compound may further include another ring structure. The other ring structure included may be a six-membered ring or may be a ring structure, such as a five-membered ring, other than a six-membered ring. The other ring structure may have an element having a lone pair or may be free of an element having a lone pair. For example, the heterocyclic compound included in the intermediate layer 70 includes one or more six-membered rings and at least one of the six-membered rings included in the heterocyclic compound includes an element having a lone pair.

The heterocyclic compound may be a heterocyclic aromatic compound (i.e., a heterocyclic compound having aromaticity). The heterocyclic compound having aromaticity refers to a heterocyclic compound having (4n+2) π electrons (n=0 to 7). Since the intermediate layer 70 includes the heterocyclic aromatic compound, it is possible to repel an X ion and effectively transfer an electron to the electron transport layer 30 or, in the case that the solar cell does not include the electron transport layer 30, to the first electrode 20. Hence, the solar cell 100 configured as described above can further enhance the photoelectric conversion efficiency and the thermal resistance.

In the above heterocyclic compound, the number of elements having a lone pair and included in the six-membered ring may be one. In this case, steric hindrance between the heterocyclic compounds is less likely to happen in the intermediate layer 70, and thus the intermediate layer 70 formed is likely to be dense.

The solar cell 100 has excellent thermal resistance. The solar cell 100 can also have excellent light resistance.

Upon irradiation of the solar cell 100 with light, the photoelectric conversion layer 40 absorbs the light to produce excited electrons and holes. The excited electrons transfer to the first electrode 20 through the electron transport layer 30. On the other hand, the holes formed in the photoelectric conversion layer 40 transfer to the second electrode 60 through the hole transport layer 50. The solar cell 100 can thereby draw out an electric current from the first electrode 20 as a negative electrode and the second electrode 60 as a positive electrode.

As shown in FIG. 3, the photoelectric conversion layer 40 and the intermediate layer 70 may be disposed in contact with each other. This makes it easy to repel an X ion at the interface between the intermediate layer 70 and the photoelectric conversion layer 40 in a dark state. This also makes it easy to suppress a cathode reaction at the interface of the photoelectric conversion layer 40 on the electron transport layer 30 side under light irradiation. Hence, the solar cell 100 has excellent photoelectric conversion efficiency, excellent thermal resistance, and excellent light resistance.

The components of the solar cell 100 will be specifically described hereinafter.

### (Substrate 10)

The substrate 10 is an accessory component. The substrate 10 supports the layers in the solar cell. The substrate 10 can be formed using a transparent material. A glass substrate or a plastic substrate, for example, can be used as the substrate 10. The plastic substrate may be, for example, a plastic film. When the second electrode 60 has a light-transmitting property, the material of the substrate 10 may be a material not having a light-transmitting property. For example, a metal, a ceramic, or a resin material having a low light-transmitting property can be used as the material of the substrate 10.

When the first electrode 20 is strong enough to support the layers, the substrate 10 may be omitted.

### (First Electrode 20)

The first electrode 20 has electrical conductivity.

In the case where the solar cell 100 does not include the electron transport layer 30, the first electrode 20 is made of a material incapable of forming an ohmic contact with the photoelectric conversion layer 40. Moreover, the first electrode 20 has a property of blocking holes from the photoelectric conversion layer 40. The property of blocking holes from the photoelectric conversion layer 40 is a property of allowing only electrons formed in the photoelectric conversion layer 40 to pass and not allowing holes to pass. A material having such a property is a material whose Fermi energy is higher than the energy at an upper part of the valence band of the photoelectric conversion layer 40. The material may be a material whose Fermi energy is higher than the Fermi energy of the photoelectric conversion layer 40. The material is specifically aluminum.

In the case where the solar cell 100 includes the electron transport layer 30, the first electrode 20 does not necessarily have the property of blocking holes from the photoelectric conversion layer 40. That is, the material of the first electrode 20 may be a material capable of forming an ohmic contact with the photoelectric conversion layer 40.

The first electrode 20 has a light-transmitting property. For example, the first electrode 20 allows visible to near-infrared light to pass therethrough. The first electrode 20 can be formed, for example, using a transparent electrically conductive metal oxide and/or a transparent electrically conductive metal nitride. Examples of the material include: titanium oxide doped with at least one selected from the group consisting of lithium, magnesium, niobium, and fluorine; gallium oxide doped with at least one selected from the group consisting of tin and silicon; gallium nitride doped with at least one selected from the group consisting of silicon and oxygen; tin oxide doped with at least one selected from the group consisting of antimony and fluorine; zinc oxide doped with at least one selected from the group consisting of boron, aluminum, gallium, and indium; indium-tin composite oxide; and their composites.

The first electrode 20 can be formed using a non-transparent material to have a pattern that allows light to pass therethrough. The pattern that allows light to pass therethrough is, for example, a linear pattern, a wave line pattern, a lattice pattern, or a perforated-metal-like pattern where a lot of small through holes are regularly or irregularly arranged. When the first electrode 20 has any of these patterns, light can pass through portions without the electrode material. Examples of the non-transparent electrode material include platinum, gold, silver, copper, aluminum, rhodium, indium, titanium, iron, nickel, tin, zinc, and alloys including any of these. Alternatively, an electrically conductive carbon material can be used.

The transmittance of the first electrode 20 may be, for example, 50% or more, or 80% or more. The wavelength of light that is to pass through the first electrode 20 depends on the absorption wavelength of the photoelectric conversion layer 40. The thickness of the first electrode 20 is, for example, 1 nm or more and 1000 nm or less.

### (Electron Transport Layer 30)

The electron transport layer 30 is disposed between the photoelectric conversion layer 40 and the first electrode 20. The electron transport layer 30 makes it possible to efficiently transfer electrons formed in the photoelectric conversion layer 40 to the first electrode 20. Consequently, an electric current can be efficiently drawn out, and thus the photoelectric conversion efficiency of the solar cell 100 can be enhanced.

The electron transport layer 30 includes an electron transport material. The electron transport material is a material that transports an electron. The electron transport material can be a semiconductor. The electron transport layer 30 may be a semiconductor having a band gap of 3.0 eV or more. When the electron transport layer 30 is made of a semiconductor having a band gap of 3.0 eV or more, visible light and infrared light can pass therethrough and reach the photoelectric conversion layer 40.

Examples of the electron transport material include inorganic n-type semiconductors.

For example, an oxide of a metal element, a nitride of a metal element, and a perovskite oxide can be used as the inorganic n-type semiconductor. For example, an oxide of Cd, Zn, In, Pb, Mo, W, Sb, Bi, Cu, Hg, Ti, Ag, Mn, Fe, V, Sn, Zr, Sr, Ga, Si, or Cr can be used as the oxide of metal element. More specific examples of the oxide of metal element include TiO₂ and SnO₂. The nitride of metal element is, for example, GaN. The perovskite oxide is, for example, SrTiO₃ or CaTiO₃.

The electron transport layer 30 may be formed of a substance having a band gap of more than 6.0 eV. Examples of the substance having a band gap of more than 6.0 eV include halides, such as lithium fluoride and calcium fluoride, of alkali metals and alkaline earth metals, alkali metal oxides such as magnesium oxide, and silicon dioxide. In this case, the electron transport layer 30 has a thickness of, for example, 10 nm or less to secure the electron transport capability of the electron transport layer 30.

The electron transport layer 30 may include a plurality of layers made of different materials. The electron transport layer 30 may be composed of a single layer.

### (Photoelectric Conversion Layer 40)

The photoelectric conversion layer 40 includes a perovskite compound.

The perovskite compound can be represented by a composition formula ABX₃. Here, A is a monovalent cation, B is a divalent cation, and X is a monovalent anion.

Examples of the monovalent cation A include an organic cation and an alkali metal cation.

Examples of the organic cation include a methylammonium cation (CH₃NH₃⁺), a formamidinium cation (HC(NH₂)₂⁺), an ethylammonium cation (CH₃CH₂NH₃⁺), and a guanidinium cation (CH₆N₃⁺).

Examples of the alkali metal cation include a potassium cation (K⁺), a cesium cation (Cs⁺), and a rubidium cation (Rb⁺).

Examples of the divalent cation B include a lead cation (Pb²⁺) and a tin cation (Sn²⁺).

Examples of the monovalent anion X include a halogen anion.

The sites of each of A, B, and X may be occupied by different ions.

The photoelectric conversion layer 40 may have a thickness of 50 nm or more and 10 μm or less.

The photoelectric conversion layer 40 can be formed by an application technique involving a solution, a printing technique, a deposition technique, or the like. The photoelectric conversion layer 40 may be formed by cutting a perovskite compound.

The photoelectric conversion layer 40 may include a perovskite compound represented by the composition formula ABX₃ as its main component. Saying that “the photoelectric conversion layer 40 includes a perovskite compound represented by the composition formula ABX₃ as its main component” herein means that the perovskite compound represented by the composition formula ABX₃ accounts for 90 mass % or more of the photoelectric conversion layer 40. The perovskite compound represented by the composition formula ABX₃ may account for 95 mass % or more of the photoelectric conversion layer 40. The photoelectric conversion layer 40 may consist of the perovskite compound represented by the composition formula ABX₃. The photoelectric conversion layer 40 is required to include the perovskite compound represented by the composition formula ABX₃, and may include a defect or an impurity.

The photoelectric conversion layer 40 may further include an additional compound different from the perovskite compound represented by the composition formula ABX₃. Examples of the additional compound include compounds having a Ruddlesden-Popper layered perovskite structure.

### (Hole Transport Layer 50)

The hole transport layer 50 is disposed, for example, between the photoelectric conversion layer 40 and the second electrode 60. The hole transport layer 50 makes it possible to efficiently transfer holes formed in the photoelectric conversion layer 40 to the second electrode 60. Consequently, an electric current can be efficiently drawn out, and thus the photoelectric conversion efficiency of the solar cell 100 can be enhanced.

The hole transport layer 50 includes a hole transport material. The hole transport material is a material that transports holes. The hole transport material can be an organic substance or an inorganic semiconductor.

Examples of the organic substance include triphenylamine, triallylamine, phenylbenzidine, phenylenevinylene, tetrathiafulvalene, vinylnaphthalene, vinylcarbazole, thiophene, aniline, pyrrole, carbazole, triptycene, fluorene, azulene, pyrene, pentacene, perylene, acridine, and phthalocyanine.

Typical examples of the organic substance used as the hole transport material include 2,2′,7,7′-tetrakis-(N,N-di-p-methoxyphenylamine)9,9′-spirobifluorene, poly[bis(4-phenyl)(2,4,6-trimethylphenyl)amine] (which may be hereinafter abbreviated as “PTAA”), poly(3-hexylthiophene-2,5-diyl), poly(3,4-ethylenedioxythiophene), and copper phthalocyanine.

The inorganic semiconductor used as the hole transport material is a p-type semiconductor. Examples of the inorganic semiconductor include Cu₂O, CuGaO₂, CuSCN, CuI, NiOₓ, MoOₓ, V₂O₅, and carbon materials such as graphene oxide.

The hole transport layer 50 may include a plurality of layers made of different materials. For example, the hole transport properties of the hole transport layer 50 are improved by stacking a plurality of layers such that the ionization potential (or the HOMO level) of the hole transport layer 50 becomes shallower layer by layer, the plurality of layers being made of different materials, the plurality of layers having ionization potentials being lower than that of the photoelectric conversion layer 40.

The thickness of the hole transport layer 50 may be 1 nm or more and 1000 nm or less, or 10 nm or more and 50 nm or less. In this case, sufficiently high hole transport properties can be exhibited and a low resistance can be maintained; therefore, highly efficient photovoltaic power generation can be achieved.

An application technique, a printing technique, a deposition technique, or the like can be adopted as the technique for forming the hole transport layer 50. The same can be said to the photoelectric conversion layer 40. Examples of the application technique include doctor blade coating, bar coating, spraying, dip coating, and spin coating. Examples of the printing technique include screen printing. If needed, the hole transport layer 50 may be formed using a mixture of a plurality of materials and then compressed or fired. In the case that the material of the hole transport layer 50 is a low-molecular-weight organic substance or an inorganic semiconductor, the hole transport layer 50 can be produced by vacuum deposition.

The hole transport layer 50 may include, as an additive, at least one selected from the group consisting of a supporting electrolyte, a solvent, and a dopant. The supporting electrolyte and the solvent stabilize holes in the hole transport layer 50. The dopant increases the number of holes in the hole transport layer 50.

Examples of the supporting electrolyte include an ammonium salt, an alkaline earth metal salt, and a transition metal salt. Examples of the ammonium salt include tetrabutylammonium perchlorate, tetraethylammonium hexafluorophosphate, an imidazolium salt, and a pyridinium salt. Examples of the alkali metal salt include lithium perchlorate and potassium tetrafluoroborate. Examples of the alkaline earth metal salt include calcium(II) bis(trifluoromethanesulfonyl)imide. Examples of the transition metal salt include zinc(II) bis(trifluoromethanesulfonyl)imide and tris[4-tert-butyl-2-(1H-pyrazole-1-yl)pyridine]cobalt(III) tris(trifluoromethanesulfonyl).

Examples of the dopant include fluorine-containing aromatic boron compounds such as tris(pentafluorophenyl)borane.

The solvent included in the hole transport layer 50 may be excellent in ion conductivity. The solvent may be an aqueous solvent or an organic solvent. To make the solute more stable, the solvent included in the hole transport layer 50 may be an organic solvent. Specific examples thereof include heterocyclic compound solvents such as tert-butylpyridine, pyridine, and n-methylpyrrolidone.

An ionic liquid may be used alone as the solvent, or a mixture of an ionic liquid and another type of solvent may be used as the solvent. Ionic liquids are desirable for their low volatility and high flame retardancy.

Examples of the ionic liquid include imidazolium ionic liquids such as 1-ethyl-3-methylimidazolium tetracyano borate, pyridine ionic liquids, alicyclic amine ionic liquids, aliphatic amine ionic liquids, and azonium amine ionic liquids.

The solar cell 100 does not necessarily include the hole transport layer 50.

### (Second Electrode 60)

The second electrode 60 has electrical conductivity.

In the case where the solar cell 100 does not include the hole transport layer 50, the second electrode 60 is made of a material incapable of forming an ohmic contact with the photoelectric conversion layer 40. Moreover, the second electrode 60 has a property of blocking electrons from the photoelectric conversion layer 40. The property of blocking electrons from the photoelectric conversion layer 40 is a property of allowing only holes formed in the photoelectric conversion layer 40 to pass and not allowing electrons to pass. A material having such a property is a material whose Fermi energy is lower than the energy at a lower part of the conduction band of the photoelectric conversion layer 40. The material may be a material whose Fermi energy is lower than the Fermi energy of the photoelectric conversion layer 40. Specific examples of the material include platinum, gold, and carbon materials such as graphene.

In the case where the solar cell 100 includes the hole transport layer 50, the second electrode 60 does not necessarily have the property of blocking electrons from the photoelectric conversion layer 40. That is, the material of the second electrode 60 may be a material capable of forming an ohmic contact with the photoelectric conversion layer 40. Therefore, the second electrode 60 can be formed to have a light-transmitting property.

An electrode that is the first electrode 20 or the second electrode 60 and that is configured to allow light to be incident thereon needs to have a light-transmitting property. That is, one of the first electrode 20 and the second electrode 60 does not necessarily have a light-transmitting property. That is, one of the first electrode 20 and the second electrode 60 does not necessarily include a material having a light-transmitting property, or does not necessarily have a pattern including an opening portion that allows light to pass therethrough.

### (Intermediate Layer 70)

As described above, the intermediate layer 70 includes the heterocyclic compound. The heterocyclic compound includes the six-membered ring including an element having a lone pair. As described above, the heterocyclic compound may further include another ring structure. The other ring structure included may be a six-membered ring or may be a ring structure, such as a five-membered ring, other than a six-membered ring. The other ring structure may have an element having a lone pair or may be free of an element having a lone pair. The intermediate layer 70 is required to be provided between the electron transport layer 30 and the photoelectric conversion layer 40. The intermediate layer 70 may have a structure obviously in a layer shape or does not necessarily have a structure obviously in a layer shape. That is, the intermediate layer 70 in the present embodiment is the above heterocyclic compound that is present in at least part of a region intermediate between the electron transport layer 30 and the photoelectric conversion layer 40 (the region is, for example, the interface between the electron transport layer 30 and the photoelectric conversion layer 40). For example, the intermediate layer 70 does not necessarily coat the entire surface of the electron transport layer 30 on the photoelectric conversion layer 40 side (i.e., the intermediate layer 70 may be present in a part of the region intermediate between the electron transport layer 30 and the photoelectric conversion layer 40), or may coat the entire surface of the electron transport layer 30 on the photoelectric conversion layer 40 side.

The heterocyclic compound may include a condensed ring including the above six-membered ring. The number of rings included in this condensed ring may be two or more, or may be two or three.

The heterocyclic compound may include a condensed ring of the above six-membered ring and a benzene ring. While efficiently repelling an X ion by the lone pair included in the six-membered ring, the heterocyclic compound having such a structure can effectively transfer an electron by its benzene ring to the electron transport layer 30 or, in the case that the solar cell does not include the electron transport layer 30, the first electrode 20. Hence, the photoelectric conversion efficiency of the solar cell 100 configured as described above can be further enhanced.

The element having a lone pair may be at least one selected from the group consisting of nitrogen, oxygen, sulfur, and phosphorus. In this case, the photoelectric conversion efficiency, the thermal resistance, and the light resistance of the solar cell 100 can be enhanced.

The heterocyclic compound may include at least one selected from the group consisting of a pyridine skeleton, a pyrazine skeleton, a pyrimidine skeleton, a pyridazine skeleton, a triazine skeleton, a tetrazine skeleton, a quinoline skeleton, an isoquinoline skeleton, a quinoxaline skeleton, a quinazoline skeleton, a cinnoline skeleton, a pteridine skeleton, a phthalazine skeleton, an acridine skeleton, a tetrahydropyran skeleton, a dioxane skeleton, a xanthene skeleton, a morpholine skeleton, a dithiane skeleton, a thioxanthene skeleton, a phenoxazine skeleton, and a phosphorine skeleton. Each of these skeletons includes one or more six-membered rings, and at least one of the six-membered rings includes an element having a lone pair. That makes it possible to efficiently repel an X ion in a dark state, and therefore the photoelectric conversion efficiency and the thermal resistance of the solar cell 100 can be enhanced. If, instead of a six-membered ring, a heterocycle smaller than a six-membered ring (such as a three-membered ring, a four-membered ring, or a five-membered ring) has a lone pair, repulsion between the lone pair and an X ion is weaker because the lone pair is farther from the photoelectric conversion layer 40.

The heterocyclic compound may have at least one substituent selected from the group consisting of —CO, —PO, and —SiO. The oxygen atom included in —CO, —PO, and —SiO functions as an anchor, and terminates the electron transport layer 30 (or a porous layer 80 described later). As for the solar cell 100 including neither the electron transport layer 30 nor the porous layer 80, the above oxygen atom terminates the first electrode 20. Hence, the electron transport layer 30 is not in direct contact with the photoelectric conversion layer 40. Consequently, the lone pair facing the photoelectric conversion layer 40 efficiently repels an X ion in a dark state, and a cathode reaction can be suppressed under light irradiation. Thus, the photoelectric conversion efficiency, the thermal resistance, and the light resistance of the solar cell 100 can be enhanced.

The above six-membered ring including an element having a lone pair may have at least one substituent selected from the group consisting of —F, —Cl, —Br, and —I. In the case where the heterocyclic compound includes two or more such six-membered rings, at least one of the six-membered rings may have at least one substituent selected from the group consisting of —F, —Cl, —Br, and —I. Such a compound is, for example, 2-chloroquinoline-4-carboxylic acid. A lone pair of the halogen group thereof can further reduce concentration of X ions. Therefore, the photoelectric conversion efficiency, the thermal resistance, and the light resistance of the solar cell 100 can further be enhanced. The halogen group has a small impact on arrangement of the heterocyclic compound in the intermediate layer 70 because steric hindrance by a halogen group is relatively small.

The heterocyclic compound may be at least one selected from the group consisting of quinolinecarboxylic acid, isonicotinic acid, picolinic acid, nicotinic acid, 2-chloroquinoline-4-carboxylic acid, 9-acridinecarboxylic acid hydrate, xanthene-9-carboxylic acid, and sodium quinaldinate. In the above case, the photoelectric conversion efficiency, the thermal resistance, and the light resistance of the solar cell 100 can be enhanced.

The intermediate layer 70 may further include a compound different from the heterocyclic compound.

The intermediate layer 70 is formed, for example, by a chemical vapor deposition technique or a solution application technique. A portion of the heterocyclic compound included in the intermediate layer 70 terminates a grain boundary of the photoelectric conversion layer 40 or a surface defect thereof. In the case where the intermediate layer 70 does not sufficiently coat the surface of the electron transport layer 30, the electron transport layer 30 can have a portion in contact with the photoelectric conversion layer 40. In the case where the heterocyclic compound includes an electrically conductive skeleton such as a benzene ring, the intermediate layer 70 does not prevent electron transfer from the photoelectric conversion layer 40 to the electron transport layer 30 or the first electrode 20.

### (Method for Manufacturing Intermediate Layer)

An example of the method for producing the intermediate layer 70 will be described. A solution application technique will be described here, but a formation technique is not limited thereto.

First, a solution containing the heterocyclic compound is produced. The solution is obtained by dissolving the heterocyclic compound in pure water or an organic solvent.

For example, a solvent mixture containing tetrahydrofuran and ethanol at a volume ratio of 1:1 is used as the organic solvent.

The heterocyclic compound concentration in the solution is, for example, 0.001 g/L or more and 10 g/L or less.

The solution prepared is applied to the electron transport layer 30 or the later-described porous layer 80.

Examples of the application technique include doctor blade, bar coating, spraying, dip coating, and spin coating.

After the application of the heterocyclic compound solution, an annealing treatment is performed.

The annealing treatment includes, for example, annealing at a temperature of 85° C. to 115° C. for 10 seconds to 30 minutes using a hot plate.

By natural cooling to room temperature after the annealing treatment, the intermediate layer 70 is produced on the electron transport layer 30 or the first electrode 20.

### (Method for Manufacturing Solar Cell 100)

The solar cell 100 can be produced, for example, by the following method.

First, the first electrode 20 is formed on a surface of the substrate 10 by chemical vapor deposition or sputtering. Next, the electron transport layer 30 is formed by chemical vapor deposition, sputtering, or solution application. Then, the intermediate layer 70 is formed on the electron transport layer 30 by the above method. Subsequently, the photoelectric conversion layer 40 is formed on the intermediate layer 70. For example, a perovskite compound may be cut to a given thickness to obtain the photoelectric conversion layer 40, which may be then disposed on the intermediate layer 70. Next, the hole transport layer 50 is formed on the photoelectric conversion layer 40 by chemical vapor deposition, sputtering, or solution application. Then, the second electrode 60 is formed on the hole transport layer 50 by chemical vapor deposition or sputtering. The solar cell 100 can be obtained in the above manner.

### Second Embodiment

A second embodiment will be described hereinafter. Descriptions of the features specified in the first embodiment may be omitted as appropriate.

A solar cell of the second embodiment includes a porous layer in addition to the configuration of the solar cell of the first embodiment. The porous layer is disposed between the electron transport layer and the intermediate layer.

The above configuration facilitates formation of the intermediate layer. When the porous layer is provided, the material of the intermediate layer enters a pore of the porous layer, which then serves as a foothold for the intermediate layer. This makes it unlikely that the material of the intermediate layer is repelled by the surface of the porous layer or aggregates on the surface of the porous layer. Therefore, the intermediate layer can be easily formed as a uniform film. Furthermore, the porous layer may increase the optical path length of light passing through the photoelectric conversion layer by causing light scattering.

FIG. 4 schematically shows a cross-sectional view of a solar cell 200 of the second embodiment.

The solar cell 200 includes the substrate 10, the first electrode 20, the electron transport layer 30, the porous layer 80, an intermediate layer 71, the photoelectric conversion layer 40, the hole transport layer 50, and the second electrode 60 in this order.

The porous layer 80 is formed on the electron transport layer 30, for example, by an application technique. In the case where the solar cell 200 does not include the electron transport layer 30, the porous layer 80 is formed on the first electrode 20.

A pore structure provided by the porous layer 80 serves as a foundation at the time of formation of the intermediate layer 71. The porous layer 80 does not prevent light absorption by the photoelectric conversion layer 40 and electron transfer from the photoelectric conversion layer 40 to the electron transport layer 30.

The porous layer 80 includes a porous body. The porous body includes a pore.

The porous body is made of, for example, continuous insulating particles or continuous semiconductor particles. The insulating particles are, for example, aluminum oxide particles or silicon oxide particles. The semiconductor particles are, for example, inorganic semiconductor particles. The inorganic semiconductor is, for example, a metal oxide, a perovskite oxide of a metal element, a metal sulfide, or a metal chalcogenide. The metal oxide is, for example, an oxide of Cd, Zn, In, Pb, Mo, W, Sb, Bi, Cu, Hg, Ti, Ag, Mn, Fe, V, Sn, Zr, Sr, Ga, Si, or Cr. The metal oxide is, for example, TiO₂. The perovskite oxide of a metal element is, for example, SrTiO₃ or CaTiO₃. The metal sulfide is, for example, CdS, ZnS, In₂S₃, PbS, Mo₂S, WS₂, Sb₂S₃, Bi₂S₃, ZnCdS₂, or Cu₂S. The metal chalcogenide is, for example, CsSe, In₂Se₃, WSe₂, HgS, PbSe, or CdTe.

The thickness of the porous layer 80 may be 0.01 μm or more and 10 μm or less, or 0.05 μm or more and 1 μm or less.

Regarding surface roughness of the porous layer 80, a surface roughness factor determined by “effective area/projected area” may be 10 or greater, or 100 or greater. The projected area refers to the area of a shadow behind an object irradiated with light from the front. The effective area refers to the actual surface area of an object. The effective area can be calculated from a volume of an object, the specific surface area of the material of the object, and the bulk density of the material of the object, the volume being determined from the projected area and the thickness of the object. The specific surface area is measured, for example, by a nitrogen adsorption method.

The pore in the porous layer 80 is continuous from a portion of the porous layer 80 in contact with the intermediate layer 71 to a portion of the porous layer 80 in contact with the electron transport layer 30. That is, the pore in the porous layer 80 is continuous from one principal surface of the porous layer 80 to the other principal surface thereof. This allows the material of the intermediate layer 71 to fill the pore of the porous layer 80 and reach the surface of the electron transport layer 30. The photoelectric conversion layer 40 and the electron transport layer 30 are thus in direct contact with each other and therefore can exchange electrons therebetween.

The porous layer 80 may increase the optical path length of light passing through the photoelectric conversion layer 40 by causing light scattering. The amount of electrons and holes formed in the photoelectric conversion layer 40 is expected to increase with the increase of the optical path length.

### OTHER EMBODIMENTS

### (Supplement)

According to the description of the above embodiments, the following techniques are disclosed.

### (Technique 1)

A solar cell including a first electrode, an electron transport layer, an intermediate layer, a photoelectric conversion layer, and a second electrode, wherein
the first electrode, the electron transport layer, the intermediate layer, and the photoelectric conversion layer are disposed in this order,
the photoelectric conversion layer includes a perovskite compound,
the intermediate layer includes a heterocyclic compound, and
the heterocyclic compound includes a six-membered ring including an element having a lone pair.

The solar cell according to Technique 1 configured as described above can enhance the thermal resistance. That is, the solar cell according to Technique 1 has a configuration suitable for enhancing the thermal resistance.

### (Technique 2)

The solar cell according to Technique 1, wherein the heterocyclic compound is a heterocyclic aromatic compound.

The solar cell according to Technique 2 configured as described above can further enhance the photoelectric conversion efficiency and the thermal resistance.

### (Technique 3)

The solar cell according to Technique 1 or 2, wherein the photoelectric conversion layer and the intermediate layer are disposed in contact with each other.

The solar cell according to Technique 3 configured as described above can enhance the photoelectric conversion efficiency, the thermal resistance, and the light resistance.

### (Technique 4)

The solar cell according to any one of Techniques 1 to 3, wherein the element having the lone pair is at least one selected from the group consisting of nitrogen, oxygen, sulfur, and phosphorus.

The solar cell according to Technique 4 configured as described above can enhance the photoelectric conversion efficiency, the thermal resistance, and the light resistance.

### (Technique 5)

The solar cell according to any one of Techniques 1 to 4, wherein the heterocyclic compound includes at least one selected from the group consisting of a pyridine skeleton, a pyrazine skeleton, a pyrimidine skeleton, a pyridazine skeleton, a triazine skeleton, a tetrazine skeleton, a quinoline skeleton, an isoquinoline skeleton, a quinoxaline skeleton, a quinazoline skeleton, a cinnoline skeleton, a pteridine skeleton, a phthalazine skeleton, an acridine skeleton, a tetrahydropyran skeleton, a dioxane skeleton, a xanthene skeleton, a morpholine skeleton, a dithiane skeleton, a thioxanthene skeleton, a phenoxazine skeleton, and a phosphorine skeleton.

The solar cell according to Technique 5 configured as described above can enhance the photoelectric conversion efficiency and the thermal resistance.

### (Technique 6)

The solar cell according to any one of Techniques 1 to 5, wherein the heterocyclic compound includes at least one substituent selected from the group consisting of —CO, —PO, and —SiO.

The solar cell according to Technique 6 configured as described above can enhance the photoelectric conversion efficiency, the thermal resistance, and the light resistance.

### (Technique 7)

The solar cell according to any one of Techniques 1 to 6, wherein the six-membered ring includes at least one substituent selected from the group consisting of —F, —Cl, —Br, and —I.

The solar cell according to Technique 7 configured as described above can enhance the photoelectric conversion efficiency, the thermal resistance, and the light resistance.

### (Technique 8)

The solar cell according to any one of Techniques 1 to 7, wherein the heterocyclic compound is at least one selected from the group consisting of quinolinecarboxylic acid, isonicotinic acid, picolinic acid, nicotinic acid, 2-chloroquinoline-4-carboxylic acid, 9-acridinecarboxylic acid hydrate, xanthene-9-carboxylic acid, and sodium quinaldinate.

The solar cell according to Technique 8 configured as described above can enhance the photoelectric conversion efficiency, the thermal resistance, and the light resistance.

### (Technique 9)

The solar cell according to any one of Techniques 1 to 8, wherein the heterocyclic compound includes a condensed ring including the six-membered ring.

The solar cell according to Technique 9 configured as described above can further enhance the photoelectric conversion efficiency.

### (Technique 10)

The solar cell according to Technique 9, wherein the heterocyclic compound includes a condensed ring of the six-membered ring and a benzene ring.

The solar cell according to Technique 10 configured as described above can further enhance the photoelectric conversion efficiency.

### EXAMPLES

The present disclosure will be described hereinafter in more details with reference to Examples and Comparative Examples.

Solar cells including perovskite compounds were produced in Examples and Comparative Examples, and initial properties of the solar cells and properties thereof after a thermal resistance test and a light resistance test were evaluated.

The configurations of the solar cells of Examples 1 to 12 and Comparative Examples 1 to 3 are as shown below. The structures of the solar cells of Comparative Examples 1 and 2 each have the following configuration from which the intermediate layer is excluded. Instead of the following intermediate layers, the solar cell of Comparative Example 3 includes a layer formed using 1-naphthoic acid, i.e., a layer formed using a heterocyclic compound free of a six-membered ring including an element having a lone pair.
Substrate: a glass substrate (thickness: 0.7 mm)
First electrode: a transparent electrode; an indium-tin composite oxide layer (thickness: 200 nm)
Electron transport layer: titanium oxide (TiO₂) (thickness: 20 nm)
Photoelectric conversion layer: a layer including HC(NH₂)₂PbI₃ as its main component (thickness: 500 nm)
Intermediate layer: isoquinoline-1-carboxylic acid, 2-quinolinecarboxylic acid, 4-quinolinecarboxylic acid, 5-quinolinecarboxylic acid, 6-quinolinecarboxylic acid, 8-quinolinecarboxylic acid, 2-chloroquinoline-4-carboxylic acid, isonicotinic acid, 9-acridinecarboxylic acid hydrate, 1-naphthoic acid (each manufactured by Tokyo Chemical Industry Co., Ltd.), or 7-quinolinecarboxylic acid (manufactured by Fluorochem Ltd.)
Hole transport layer: a buffer layer and a layer including PTAA as its main component (thickness: 50 nm)
Second electrode: Au (thickness: 200 nm)

The configurations of the solar cells of Example 13, Example 14, and Comparative Example 4 are as follows. The structure of the solar cell of Comparative Example 4 has the following configuration from which the intermediate layer is excluded.
Substrate: a glass substrate (thickness: 0.7 mm)
First electrode: a transparent electrode; an indium-tin composite oxide layer (thickness: 200 nm)
Electron transport layer: titanium oxide (TiO₂) (thickness: 20 nm)
Porous layer: titanium oxide (TiO₂) having a mesoporous structure
Photoelectric conversion layer: a layer including HC(NH₂)₂PbI₃ as its main component (thickness: 500 nm)
Intermediate layer: 4-quinolinecarboxylic acid or 5-quinolinecarboxylic acid (each manufactured by Tokyo Chemical Industry Co., Ltd.)
Hole transport layer: a buffer layer and a layer including PTAA as its main component (thickness: 50 nm)
Second electrode: Au (thickness: 200 nm)

### <Production of Solar Cell>

### Example 1

First, a glass substrate having a thickness of 0.7 mm was prepared. An indium-tin composite oxide layer was formed on the substrate by sputtering. A first electrode was formed in this manner.

Next, a titanium oxide layer was formed on the first electrode by sputtering. An electron transport layer was formed in this manner.

Next, a solution containing the heterocyclic compound was applied to the electron transport layer by spin coating. This was followed by annealing at 100° C. for 10 minutes on a hot plate. An intermediate layer was formed in this manner. The solution contained isoquinoline-1-carboxylic acid as a solute and a solvent mixture containing tetrahydrofuran and ethanol at a volume ratio of 1:1 as a solvent such that the isoquinoline-1-carboxylic acid concentration was 1.6 mmol/L.

Next, a raw material solution containing a photoelectric conversion material was applied by spin coating to form a photoelectric conversion layer including a perovskite compound. The raw material solution contained 0.95 mol/L lead(II) iodide (manufactured by Tokyo Chemical Industry Co., Ltd.), 0.05 mol/L lead(II) bromide (manufactured by Tokyo Chemical Industry Co., Ltd.), 0.79 mol/L formamidinium iodide (manufactured by GreatCell Solar Limited), 0.11 mol/L methylammonium iodide (manufactured by GreatCell Solar Limited), 0.05 mol/L methylammonium bromide (manufactured by GreatCell Solar Limited), 0.05 mol/L cesium iodide (manufactured by Iwatani Corporation), and 0.025 mol/L rubidium iodide (manufactured by Iwatani Corporation). The solvent of the raw material solution was a solvent mixture containing dimethyl sulfoxide (DMSO) (manufactured by Acros) and N, N-dimethylformamide (DMF) (manufactured by Acros) at a volume ratio of DMSO:DMF=1:4.

Next, a raw material solution containing a hole transport material was applied to the photoelectric conversion layer by spin coating to form a hole transport layer. Specifically, first, a buffer layer including 2-phenylethylamine hydroiodide (manufactured by Tokyo Chemical Industry Co., Ltd.) was formed. A layer including PTAA as its main component (and, as additives, 4-tert-butylpyridine (manufactured by Tokyo Chemical Industry Co., Ltd.) and lithium bis(trifluoromethanesulfonyl)imide (manufactured by Sigma-Aldrich Co., LLC.)) was formed on the buffer layer.

The solvent of a raw material solution of the buffer layer was 2-propanol (manufactured by Wako Pure Chemical Industries, Ltd.), and the solution contained 1 g/L 2-phenylethylamine hydroiodide. The solvent of a raw material solution of the layer including PTAA as its main component was toluene (manufactured by Acros), and the solution contained 10 g/L PTAA.

Subsequently, an Au film was deposited on the hole transport layer by vacuum deposition to form a second electrode.

The solar cell of Example 1 was obtained in the above manner.

### Example 2

In Example 2, 2-quinolinecarboxylic acid was used as the heterocyclic compound for formation of the intermediate layer. Except for that, the solar cell of Example 2 was obtained in the same manner as in Example 1.

### Example 3

In Example 3, 4-quinolinecarboxylic acid was used as the heterocyclic compound for formation of the intermediate layer. Except for that, the solar cell of Example 3 was obtained in the same manner as in Example 1.

### Example 4

In Example 4, 5-quinolinecarboxylic acid was used as the heterocyclic compound for formation of the intermediate layer. Except for that, the solar cell of Example 4 was obtained in the same manner as in Example 1.

### Example 5

In Example 5, the raw material solution of the photoelectric conversion material was a solution containing 0.6 mol/L lead(II) iodide (manufactured by Tokyo Chemical Industry Co., Ltd.), 0.4 mol/L lead(II) bromide (manufactured by Tokyo Chemical Industry Co., Ltd.), 0.55 mol/L formamidinium iodide (manufactured by GreatCell Solar Limited), 0.02 mol/L methylammonium iodide (manufactured by GreatCell Solar Limited), 0.24 mol/L formamidinium bromide (manufactured by GreatCell Solar Limited), 0.14 mol/L methylammonium bromide (manufactured by GreatCell Solar Limited), 0.05 mol/L cesium iodide (manufactured by Iwatani Corporation), and 0.025 mol/L rubidium iodide (manufactured by Iwatani Corporation).

As for the hole transport layer, the buffer layer included n-butylammoniumbromide (manufactured by GreatCell Solar Limited) instead of 2-phenylethylamine hydroiodide. The layer including PTAA as its main component included, as an additive, tris(pentafluorophenyl)borane (manufactured by Tokyo Chemical Industry Co., Ltd.) instead of 4-tert-butylpyridine and lithium bis(trifluoromethanesulfonyl)imide.

Except for the above, the solar cell of Example 5 was obtained in the same manner as in Example 3.

### Example 6

In Example 6, 6-quinolinecarboxylic acid was used as the heterocyclic compound for formation of the intermediate layer. Except for that, the solar cell of Example 6 was obtained in the same manner as in Example 5.

### Example 7

In Example 7, 7-quinolinecarboxylic acid was used as the heterocyclic compound for formation of the intermediate layer. Except for that, the solar cell of Example 7 was obtained in the same manner as in Example 5.

### Example 8

In Example 8, 8-quinolinecarboxylic acid was used as the heterocyclic compound for formation of the intermediate layer. Except for that, the solar cell of Example 8 was obtained in the same manner as in Example 5.

### Example 9

In Example 9, the photoelectric conversion layer had a thickness of 600 nm. Except for that, the solar cell of Example 9 was obtained in the same manner as in Example 5.

### Example 10

In Example 10, 2-chloroquinoline-4-carboxylic acid was used as the heterocyclic compound for formation of the intermediate layer. Except for that, the solar cell of Example 10 was obtained in the same manner as in Example 9.

### Example 11

In Example 11, isonicotinic acid was used as the heterocyclic compound for formation of the intermediate layer. Except for that, the solar cell of Example 11 was obtained in the same manner as in Example 9.

### Example 12

In Example 12, 9-acridinecarboxylic acid hydrate was used as the heterocyclic compound for formation of the intermediate layer. Except for that, the solar cell of Example 12 was obtained in the same manner as in Example 9.

### Example 13

In Example 13, titanium oxide having a mesoporous structure was used as the porous layer. 30NR-D (manufactured by GreatCell Solar Limited) was applied to the electron transport layer by spin coating, followed by firing at 500° C. for 30 minutes. The porous layer was formed in this manner.

An intermediate layer was formed on the porous layer. 4-Quinolinecarboxylic acid was used as the heterocyclic compound for formation of the intermediate layer.

As for the hole transport layer, the buffer layer included n-butyl ammonium bromide (manufactured by GreatCell Solar Limited) instead of 2-phenylethylamine hydroiodide. The layer including PTAA as its main component included, as an additive, tris(pentafluorophenyl)borane (manufactured by Tokyo Chemical Industry Co., Ltd.) instead of 4-tert-butylpyridine and lithium bis(trifluoromethanesulfonyl)imide.

Except for the above, the solar cell of Example 13 was obtained in the same manner as in Example 2.

### Example 14

In Example 14, 5-quinolinecarboxylic acid was used as the heterocyclic compound for formation of the intermediate layer. Except for that, the solar cell of Example 14 was obtained in the same manner as in Example 13.

### Comparative Example 1

In Comparative Example 1, no intermediate layer was formed. Except for that, the solar cell of Comparative Example 1 was obtained in the same manner as in Example 1.

### Comparative Example 2

In Comparative Example 2, no intermediate layer was formed. Except for that, the solar cell of Comparative Example 2 was obtained in the same manner as in Example 5.

### Comparative Example 3

In Comparative Example 3, 1-naphthoic acid was used as the heterocyclic compound for formation of the intermediate layer. Except for that, the solar cell of Comparative Example 3 was obtained in the same manner as in Example 9.

### Comparative Example 4

In Comparative Example 4, no intermediate layer was formed. Except for that, the solar cell of Comparative Example 4 was obtained in the same manner as in Example 13.

### <Measurement of Output>

Outputs of the solar cells of Examples 1 to 12 and Comparative Examples 1 to 3 were measured.

An electrochemical analyzer (ALS440B manufactured by BAS Inc.) and a fluorescent light were used for the output measurement. Before the measurement, the light intensity was calibrated so as to be 200 lux using a silicon photodiode. A voltage scan rate was 100 mV/s. Before starting the measurement, advance adjustment by light irradiation, a long period of forward bias application, etc. was not performed. Each solar cell was masked with a black mask having a 0.1 cm² opening portion so as to fix the effective area and reduce influence of scattering light. The masked solar cell was irradiated with light from the mask (substrate) side. The output measurement was performed at room temperature in dry air (<2% RH).

### <Thermal Resistance Test>

A thermal resistance test was performed for each of the solar cells of Examples 1 to 12 and Comparative Examples 1 to 3.

First, in a nitrogen atmosphere, each solar cell was sealed in a sealing glass container using an ultraviolet-curable resin, the sealing glass container having moisture and oxygen getters adhered inside. Next, the sealed-in solar cell was maintained at 85° C. in a constant-temperature chamber for a long period of time. An output upon irradiation with 200 lux light was measured before and after the thermal resistance test. Tables 1 to 3 show the results. Tables 1 to 3 also show how long the solar cells were maintained at 85° C. in the constant-temperature chamber.

TABLE 1

Output (μW/cm²)

| | Intermediate layer | 0 h | 464 h |
|---|---|---|---|
| Example 1 | Isoquinoline-1- | 9.62 | 11.26 |
| | carboxylic acid | | |
| Example 2 | 2-Quinolinecarboxylic | 11.39 | 11.25 |
| | acid | | |
| Example 3 | 4-Quinolinecarboxylic | 12.29 | 12.08 |
| | acid | | |
| Example 4 | 5-Quinolinecarboxylic | 11.58 | 11.77 |
| | acid | | |
| Comparative | — | 10.05 | 10.93 |
| Example 1 | | | |

TABLE 2

Output (μW/cm²)

| | Intermediate layer | 0 h | 199 h |
|---|---|---|---|
| Example 5 | 4-Quinolinecarboxylic | 13.36 | 12.45 |
| | acid | | |
| Example 6 | 6-Quinolinecarboxylic | 13.15 | 10.55 |
| | acid | | |
| Example 7 | 7-Quinolinecarboxylic | 12.99 | 10.23 |
| | acid | | |
| Example 8 | 8-Quinolinecarboxylic | 13.56 | 9.28 |
| | acid | | |
| Comparative | — | 12.51 | 9.01 |
| Example 2 | | | |

TABLE 3

Output (μW/cm²)

| | Intermediate layer | 0 h | 263 h |
|---|---|---|---|
| Example 9 | 4-Quinolinecarboxylic | 15.98 | 14.85 |
| | acid | | |
| Example 10 | 2-Chloroquinoline-4- | 15.31 | 13.00 |
| | carboxylic acid | | |
| Example 11 | Isonicotinic acid | 15.97 | 15.14 |
| Example 12 | 9-Acridinecarboxylic | 14.29 | 13.69 |
| | acid hydrate | | |
| Comparative | 1-Naphthoic acid | 14.44 | 12.72 |
| Example 3 | | | |

### <Discussion>

### (On Effect of Intermediate Layer)

The solar cells of Examples 1 to 4 and the solar cell of Comparative Example 1 which is differentiated from the solar cells of Examples 1 to 4 by the absence of the intermediate layer are compared below, and the solar cells of Examples 5 to 8 and the solar cell of Comparative Example 2 which is differentiated from the solar cells of Examples 5 to 8 by the absence of the intermediate layer are compared below. As shown in Table 1, the solar cells of Examples 1 to 4 maintain a high output even after the long-term thermal resistance test compared to the solar cell of Comparative Example 1 including no intermediate layer. Moreover, as shown in Table 2, the solar cells of Examples 5 to 8 maintain a high output even after the long-term thermal resistance test compared to the solar cell of Comparative Example 2 including no intermediate layer. These results reveal that the solar cells provided with the intermediate layers have an improved thermal resistance.

The solar cells of Examples 2 to 4 have improved initial outputs (i.e., outputs before the thermal resistance test) compared to the solar cell of Comparative Example 1 including no intermediate layer. The solar cells of Examples 5 to 8 have improved initial outputs (i.e., outputs before the thermal resistance test) compared to the solar cell of Comparative Example 2 including no intermediate layer. These results reveal that the solar cells provided with the intermediate layer between the electron transport layer and the photoelectric conversion layer can have a high photoelectric conversion efficiency and a high thermal resistance.

### (On Position of Lone Pair)

When isoquinoline-1-carboxylic acid, 2-quinolinecarboxylic acid, and 8-quinolinecarboxylic acid, in which the nitrogen atom having a lone pair and included in the six-membered ring is positioned near the carboxy group (or the carbonyl group), are self-organized on the electron transport layer, the lone pair does not face the photoelectric conversion layer. When self-organized on the electron transport layer, 6-quinolinecarboxylic acid and 7-quinolinecarboxylic acid are disposed to protrude toward the photoelectric conversion layer, and thus the lone pair faces a direction parallel or slightly oblique to the photoelectric conversion layer. Meanwhile, when 4-quinolinecarboxylic acid and 5-quinolinecarboxylic acid, in which the nitrogen atom having a lone pair and included in the six-membered ring is positioned far from and opposite to the carboxy group (or the carbonyl group), are self-organized on the electron transport layer, the lone pair is disposed to face the photoelectric conversion layer. It is therefore possible to efficiently repel, in a dark state, iodine ions diffused toward the electron transport layer by heating, and thus concentration of iodine ions is reduced. Hence, the thermal resistance is enhanced more by using 4-quinolinecarboxylic acid and 5-quinolinecarboxylic acid than by using the other quinolinecarboxylic acids.

### (On Effect of Steric Hindrance)

As shown in Table 3, the initial output (0 h) and the thermal resistance of the solar cell of Example 9 are higher than those of the solar cells of Examples 10 and 12. The solar cell of Example 11 has an initial output equivalent to that of the solar cell of Example 9, but has a higher output after the long-term thermal resistance test than that of the solar cell of Example 9. That is, the thermal resistance of the solar cell of Example 11 is higher than that of the solar cell of Example 9. The quinolinecarboxylic acids of these solar cells are the same in that when the quinolinecarboxylic acid is self-organized on the electron transport layer, the nitrogen atom having a lone pair and included in the six-membered ring is positioned far from and opposite to the carboxy group (or the carbonyl group) and the lone pair is disposed to face the photoelectric conversion layer. However, compared to 4-quinolinecarboxylic acid, 2-chloroquinoline-4-carboxylic acid and 9-acridinecarboxylic acid hydrate additionally include, respectively, —Cl and a benzene ring bonded thereto. Therefore, when 2-chloroquinoline-4-carboxylic acid and 9-acridinecarboxylic acid hydrate are self-organized on the electron transport layer, the total number of lone pairs disposed to face the photoelectric conversion layer is decreased by the effect of steric hindrance. On the other hand, compared to 4-quinolinecarboxylic acid, steric hindrance occurs less for isonicotinic acid because isonicotinic acid does not include a benzene ring and only a pyridine ring is bonded to the carboxyl group (or the carbonyl group) thereof. Consequently, the total number of lone pairs disposed to face the photoelectric conversion layer increases.

Hence, it is desirable that steric hindrance occur less when the heterocyclic compound included in the intermediate layer is self-organized.

### (On Effect of Lone Pair)

As shown in Table 3, in the case where the heterocyclic compound included in the intermediate layer was 1-naphthoic acid (Comparative Example 3), the thermal resistance was lower than those of Examples 9 to 12. This indicates that since 1-naphthoic acid does not include an element having a lone pair and included in a six-membered ring, 1-naphthoic acid cannot prevent, in a dark state, concentration of iodine ions diffused toward the electron transport layer by heating. Therefore, the heterocyclic compound included in the intermediate layer needs to include an element having a lone pair.

### <Measurement of Photoelectric Conversion Efficiency>

The photoelectric conversion efficiency of each of the solar cells of Example 13, Example 14, and Comparative Example 4 was measured.

An electrochemical analyzer (ALS440B manufactured by BAS Inc.) and a xenon light source (BPS X300BA manufactured by Bunkoukeiki Co., Ltd.) were used for the measurement. Before the measurement, the light intensity was calibrated so as to be 1 Sun (100 mW/cm²) using a silicon photodiode. A voltage scan rate was 100 mV/s. Before starting the measurement, advance adjustment by light irradiation, a long period of forward bias application, etc. was not performed. Each solar cell was masked with a black mask having a 0.1 cm² opening portion so as to fix the effective area and reduce influence of scattering light. The masked solar cell was irradiated with light from the mask (substrate) side thereof. The photoelectric conversion efficiency measurement was performed at room temperature in dry air (<2% RH).

### <Light Irradiation Test>

A light irradiation test was performed for each of the solar cells of Example 13, Example 14, and Comparative Example 4.

First, in the air, each solar cell was sealed in a sealing glass container using a UV-curable resin, the sealing glass container having moisture and oxygen getters adhered inside. Next, the solar cell was irradiated from the substrate side with about 1 Sun of light for 60 hours. During the irradiation, the output was maintained around a maximum power point of the solar cell, and the substrate temperature was maintained at 50° C. After 1 hour, 15 hours, 30 hours, and 60 hours of the light irradiation, each solar cell was measured for the photoelectric conversion efficiency in the above manner. Table 4 shows the results.

TABLE 4

| | | Photoelectric conversion | | | |
|---|---|---|---|---|---|
| | | efficiency (%) | | | |
| | Intermediate layer | 1 h | 15 h | 30 h | 60 h |
| Example 13 | 4-Quinolinecarboxylic | 18.30 | 18.30 | 17.44 | 16.63 |
| | acid | | | | |
| Example 14 | 5-Quinolinecarboxylic | 14.22 | 14.54 | 14.33 | 13.53 |
| | acid | | | | |
| Comparative | N/A | 17.15 | 9.96 | 7.91 | 6.83 |
| Example 4 | | | | | |

### <Discussion>

As is obvious from Table 4, the solar cells of Examples 13 and 14 have high light resistance compared to that of Comparative Example 4 including no intermediate layer. This is because provision of the intermediate layer suppresses a cathode reaction at the interface between the electron transport layer and the photoelectric conversion layer upon light irradiation.

As shown in the above results, solar cells having high photoelectric conversion efficiency, high thermal resistance, and high light resistance were able to be obtained by providing an intermediate layer between the electron transport layer and the photoelectric conversion layer, the intermediate layer including a heterocyclic compound including a six-membered ring including an element having a lone pair.

### INDUSTRIAL APPLICABILITY

It can be said that since the solar cell of the present disclosure can greatly enhance the thermal resistance, the industrial applicability of the solar cell of the present disclosure is extremely high.

What is claimed is:

1. A solar cell comprising a first electrode, an electron transport layer, an intermediate layer, a photoelectric conversion layer, and a second electrode, wherein
the first electrode, the electron transport layer, the intermediate layer, and the photoelectric conversion layer are disposed in this order,
the photoelectric conversion layer includes a perovskite compound,
the intermediate layer includes a heterocyclic compound, and
the heterocyclic compound includes a six-membered ring including an element having a lone pair.

2. The solar cell according to claim 1, wherein the heterocyclic compound is a heterocyclic aromatic compound.

3. The solar cell according to claim 1, wherein the photoelectric conversion layer and the intermediate layer are disposed in contact with each other.

4. The solar cell according to claim 1, wherein the element having the lone pair is at least one selected from the group consisting of nitrogen, oxygen, sulfur, and phosphorus.

5. The solar cell according to claim 1, wherein the heterocyclic compound includes at least one selected from the group consisting of a pyridine skeleton, a pyrazine skeleton, a pyrimidine skeleton, a pyridazine skeleton, a triazine skeleton, a tetrazine skeleton, a quinoline skeleton, an isoquinoline skeleton, a quinoxaline skeleton, a quinazoline skeleton, a cinnoline skeleton, a pteridine skeleton, a phthalazine skeleton, an acridine skeleton, a tetrahydropyran skeleton, a dioxane skeleton, a xanthene skeleton, a morpholine skeleton, a dithiane skeleton, a thioxanthene skeleton, a phenoxazine skeleton, and a phosphorine skeleton.

6. The solar cell according to claim 1, wherein the heterocyclic compound includes at least one substituent selected from the group consisting of —CO, —PO, and —SiO.

7. The solar cell according to claim 1, wherein the six-membered ring includes at least one substituent selected from the group consisting of —F, —Cl, —Br, and —I.

8. The solar cell according to claim 1, wherein the heterocyclic compound is at least one selected from the group consisting of quinolinecarboxylic acid, isonicotinic acid, picolinic acid, nicotinic acid, 2-chloroquinoline-4-carboxylic acid, 9-acridinecarboxylic acid hydrate, xanthene-9-carboxylic acid, and sodium quinaldinate.

9. The solar cell according to claim 1, wherein the heterocyclic compound includes a condensed ring including the six-membered ring.

10. The solar cell according to claim 9, wherein the heterocyclic compound includes a condensed ring of the six-membered ring and a benzene ring.
